(19) United States
(12) Patent Application Publication
(10) Pub. No.: US 2008/0063798 A1
(43) Pub. Date: Mar. 13, 2008

(54) PRECURSORS AND HARDWARE FOR CVD AND ALD

(76) Inventors: Shreyas S. Kher, Campbell, CA (US); Son T. Nguyen, San Jose, CA (US); Pravin K. Narwankar, Sunnyvale, CA (US); Sanjeev Tandon, Sunnyvale, CA (US); Steve Jumper, Dublin, CA (US); Vincent Sermona, San Diego, CA (US)

Correspondence Address: PATTERSON & SHERIDAN, LLP, 3040 POST OAK BOULEVARD, SUITE 1500, HOUSTON, TX, 77056, US

(21) Appl. No.: 11/847,158

(22) Filed: Aug. 29, 2007

Related U.S. Application Data
(60) Provisional application No. 60/824,037, filed on Aug. 30, 2006.

(51) Int. Cl. C23C 16/22

(52) U.S. Cl. 427/255.394; 118/715; 427/255.28

(57) ABSTRACT

The present invention generally comprises an apparatus for depositing high k dielectric or metal gate materials in which toxic, flammable, or pyrophoric precursors may be used. Exhaust conduits may be placed on the liquid precursor or solid precursor delivery cabinet, the gas panel, and the water vapor generator area. The exhaust conduits permit a technician to access the apparatus without undue exposure to toxic, pyrophoric, or flammable gases that may collect within the liquid deliver cabinet, gas panel, and water vapor generator area.

### CROSS-REFERENCE TO RELATED APPLICATIONS

This application claims benefit of U.S. Provisional Patent Application Ser. No. 60/824,037 (APPM/010158L), filed Aug. 30, 2006, which is herein incorporated by reference.

### BACKGROUND OF THE INVENTION

1. Field of the Invention

Embodiments of the present invention generally relate to precursors and hardware for depositing high k dielectrics and metal gate materials using atomic layer deposition (ALD) or chemical vapor deposition (CVD).

2. Description of the Related Art

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater are being considered. Accordingly, conformal deposition of materials to form these devices is becoming increasingly important.

While conventional CVD has proved successful for device geometries and aspect ratios down to 0.15 μm, the more aggressive device geometries require an alternative deposition technique. One technique that is receiving considerable attention is ALD. During an ALD process, reactant gases are sequentially introduced into a process chamber containing a substrate. Generally, a first reactant is pulsed into the process chamber and is adsorbed onto the substrate surface. A second reactant is pulsed into the process chamber and reacts with the first reactant to form a deposited material. A purge step is typically carried out between the delivery of each reactant gas. The purge step may be a continuous purge with the carrier gas or a pulse purge between the delivery of the reactant gases.

The formation of high-k dielectric materials by oxidizing metal and silicon precursors during an ALD process is known in the art. Ozone, atomic oxygen, water are common oxidants or oxidizing sources for ALD processes. A low process temperature may be advantageously maintained during the deposition process while forming the dielectric material due to the radical state of ozone and atomic oxygen. High temperature, highly oxidizing plasma environments may also be used if the process can be controlled.

Therefore, there is a need in the art for an apparatus for high k dielectric or metal gate material deposition that may operate at a high temperature in a highly oxidizing plasma environment.

### SUMMARY OF THE INVENTION

The present invention generally comprises an apparatus for depositing high k dielectric or metal gate materials in which toxic, flammable, or pyrophoric precursors may be used. Exhaust conduits may be placed on the liquid precursor or solid precursor delivery cabinet, the gas panel, and the water vapor generator area. The exhaust conduits permit a technician to access the apparatus without undue exposure to toxic, pyrophoric, or flammable gases that may collect within the liquid deliver cabinet, gas panel, and water vapor generator area.

In one embodiment, a vapor deposition apparatus is disclosed. The apparatus comprises a liquid precursor or solid precursor delivery cabinet having an exhaust line coupled therewith, a gas panel having an exhaust line coupled therewith, a water vapor generator system having an exhaust line coupled therewith, and one or more toxic, flammable, or pyrophoric precursor sources.

In another embodiment, a vapor deposition method is disclosed. The method comprises introducing at least one precursor to an apparatus, the apparatus having a liquid precursor or solid precursor delivery cabinet, a gas panel, and a water vapor generator system, the precursor selected from the group consisting of toxic precursors, flammable precursors, and pyrophoric precursors, venting precursor gas from at least one of the liquid delivery cabinet, gas panel, or water vapor generator system, and depositing a layer on a substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic cross-sectional view of an apparatus according to one embodiment of the invention.

FIGS. 2A and 2B are schematic views of a processing system according to one embodiment of the invention.

FIG. 3 is a schematic view of a processing system according to another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises an apparatus for depositing high k dielectric materials or metal gate materials in which toxic, flammable, or pyrophoric precursors may be used. Exhaust conduits may be placed on the liquid precursor or solid precursor delivery cabinet, the gas panel, and the water vapor generator area. The exhaust conduits permit a technician to access the apparatus without undue exposure to toxic, pyrophoric, or flammable gases that may collect within the liquid precursor or solid precursor delivery cabinet, gas panel, and water vapor generator area. Exemplary high k dielectric material that may be deposited include HfO₂, HfSiO, Pr₂O₃, La₂O₅, ZrO₂, ZrSiO, Al₂O₃, LaAlO, Ta₂O₅, TaO₅, AlO₅, and TiO₅. Exemplary metal gate materials that may be deposited include TaN, TiN, TaSiN, Ru, Pt, TiAlN, and HfN. Other films may also be deposited including polysilicon, SiN, and HTO. The apparatus may be an ALD reactor or a CVD reactor.

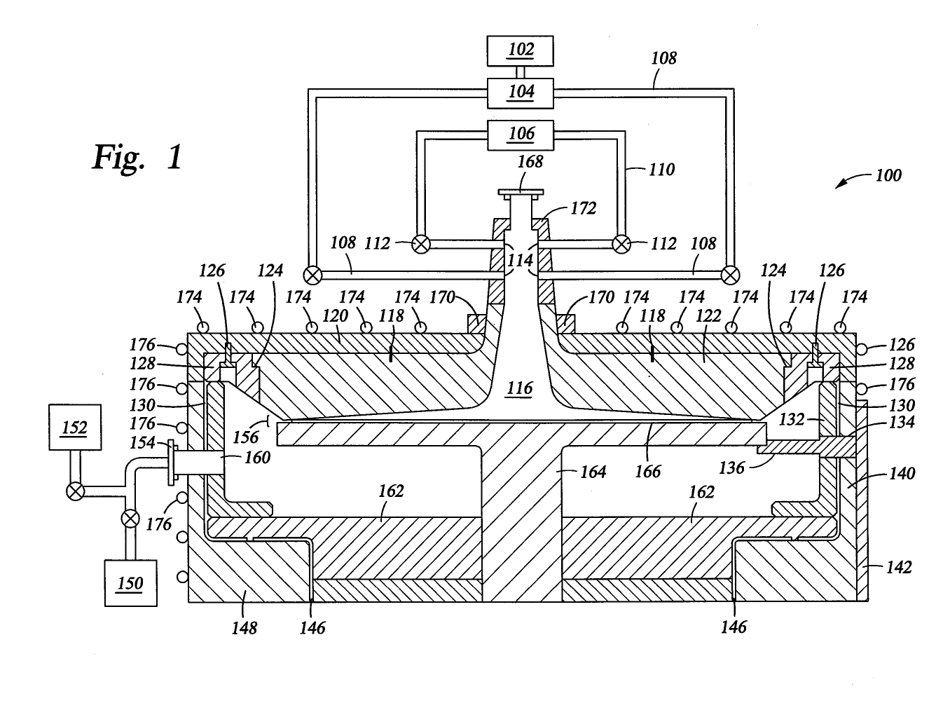

FIG. 1 depicts a schematic cross-sectional view of process chamber 100 that may be used to perform integrated circuit fabrication in accordance with embodiments described herein. Process chamber 100 may contain thermally insulating materials to operate at high temperatures (e.g., <800° C.). The process chamber 100 may contain liners made from a thermally insulating material, such as fused quartz, sapphire, pyrolytic boron nitrite (PBN) material, ceramic, derivatives thereof or combinations thereof.

Process chamber 100 generally houses substrate support pedestal 164 used to support substrate 166. Substrate support pedestal 164 may be rotatable and vertically movable within process chamber 100. Substrate support pedestal 164 may contain a heating element to control the temperature of substrate 166 thereon. Cap portion 172 is disposed on lid 120 of process chamber 100 and contains gas inlets 114. Cap portion 172 may also contain an adapter 168 for a microwave apparatus or a remote plasma apparatus used during a plasma process, such as a PE-ALD process, a pre-clean process or a post treatment process such as a nitridation process. Alternatively, adapter 168 is absent from cap portion 172.

Gas panel 106 is connected to the process chamber 100 through cap portion 172. Gas panel 106 contains at least one and as many as about ten componential sets of gas inlets 114, conduit system 108, 110, valve 112 and at least one precursor source. As illustrated in FIG. 1, gas panel 106 contains two componential sets containing gas inlets 114, conduit systems 110, valves 112, and precursor sources. Valves 112 may be fast switching valves that may pulse in the reactants or oxidizers. The precursors may be provided in a reservoir to ensure that sufficient precursor is available.

In an alternative embodiment, conduit system 108, 110 may further contain gradually expanding gas conduits forming nozzles at the ends that are also positioned in fluid communication with gas inlets 114. The nozzles or ends that are useful in some embodiments described herein are further described in commonly assigned United States Patent Publication No. 2005/0252449 A1, which is incorporated herein by reference. The gas conduit geometry prevents large temperature drops by providing passing gases a means to gradually expand through an increasing tapered flow channel. In one embodiment, the flow channel transitions from the cross-sections of delivery gas lines with internal diameter in a range from about 3 mm to about 15 mm to gas inlet 114 with a larger diameter in a range from about 10 mm to about 20 mm over a distance in a range from about 30 mm to about 100 mm. A gradual increase of the diameter of a flow channel allows the expanding gases to be in near equilibrium and prevents a rapid loss of heat to maintain a substantially constant temperature. Expanding gas conduits may comprise one or more tapered inner surfaces such as a tapered straight surface, a concave surface, a convex surface, derivatives thereof or combinations thereof or may comprise sections of one or more tapered inner surfaces (e.g., a portion tapered and a portion non-tapered).

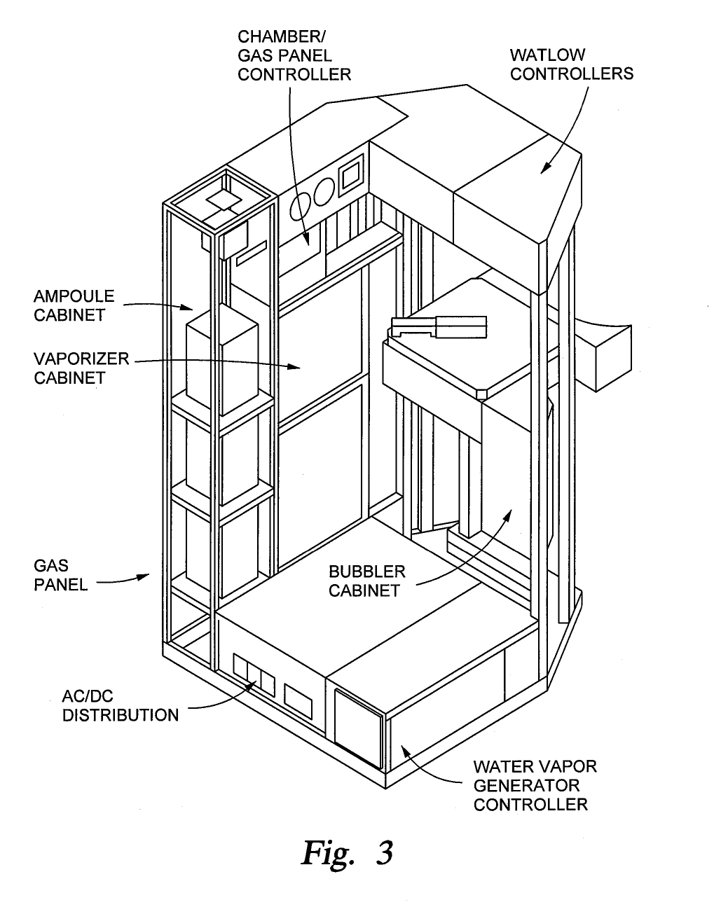

Conduit system 108, 110 contains one or several conduits and tubes connecting gas inlets 114, valves 112 and gas panel 106. Valves 112 may include a valve and a valve seat assembly containing a diaphragm and a valve seat. Pneumatically actuated valves may provide pulses of gases in time periods as low as about 0.020 seconds. Electrically actuated valves may provide pulses of gases in time periods as low as about 0.005 seconds. Generally, pneumatically and electrically actuated valves may provide pulses of gases in time periods as high as about 3 seconds. Although a higher time period for gas pulsing is possible, a typical ALD process utilizes ALD valves that generate pulses of gas while being opened for an interval of about 5 seconds or less. In one embodiment, the valves may be opened for an interval of about 3 seconds or less. In yet another embodiment, the valves may be opened for an interval of about 2 seconds or less. In one embodiment, an ALD valve pulses for an interval in a range from about 0.005 seconds to about 3 seconds. In another embodiment, the valve pulses for an interval from about 0.02 seconds to about 2 seconds. In yet another embodiment, the valve pulses for an interval from about 0.05 seconds to about 1 second. An electrically actuated valve typically requires the use of a driver coupled between the valve and the programmable logic controller. A control unit (not shown), such as a programmed personal computer, work station computer, or the like, may be included with process chamber 100, including valves 112, precursor sources, vacuum system 150, substrate support 164, WVG (Water Vapor Generator) system 104, and gas panel 106 to control processing conditions as described herein. As shown in FIG. 3, the WVG system 106 may be located under the chamber.

Gas panel 106 may provide a precursor source, a purge gas source and/or a carrier gas source used during the deposition process. A precursor source may include more than one chemical precursor (e.g., a hafnium precursor and a silicon precursor) and may include a carrier gas. A precursor source includes ampoules, bubblers, tanks, containers or cartridges. Also, a precursor source includes a WVG system 104 coupled with a source 102 in fluid communication with gas panel 106 as described herein. A purge gas source and/or a carrier gas source usually a tank, a container, a cartridge or an in-house plumbed supply system, may provide nitrogen, argon, helium, hydrogen, forming gas or combinations thereof to gas panel 106.

Gas inlets 114 may be located along the length of expanding channel 116 within cap portion 172. Not wishing to be bound by theory, gas flowing from gas inlets 114 into and through expanding channel 116 forms a circular flow. Although the exact flow pattern through expanding channel 116 is not known, it is believed that the circular flow may travel with a flow pattern such as a vortex flow, a helix flow, a spiral flow or derivative thereof through the expanding channel 116. The circular flow may be provided in a processing region located between funnel liner 122 and substrate support 164 as opposed to in a compartment separated from substrate 164. In one aspect, the vortex flow may help to establish a more efficient purge of the processing region due to the sweeping action of the circular flow across the inner surface of expanding channel 116. Also, a circular gas flow provides a consistent and conformal delivery of gas across the surface of substrate 166.

FIG. 1 depicts a schematic view of thermally insulating liners that may be used within process chamber 100 and other process chambers during deposition processes described herein. Expanding channel 116 may be formed within cap portion 172 and between funnel liner 122. Thermal isolator 170 is disposed around cap portion 172. Funnel liner 122 may be held against the underside of lid 120 by retaining ring liner 128 by aligning ledge surface 124 of retaining ring liner 128 with a ledge surface of funnel liner 122. Retaining ring liner 128 may be attached to the underside of lid 120 by fasteners 126, such as fittings, bolts, screws or pins. In one example, fastener 126 is a fitting inserted and set into a groove of retaining ring liner 128. Funnel liner 122 may also contain several pins 118 that are loosely fitted to provide the funnel liner 122 freedom to thermally expand while under a heating process. In one embodiment, funnel liner 122 becomes aligned and centered with substrate 164 after being thermally expanded. Alternatively, funnel liner 122 and retaining ring liner 128 may be formed as a single piece.

Process chamber 100 may further contain upper process liner 132 and lower process liner 162. Lower process liner 162 is disposed on a bottom surface and upper process liner 132 is disposed on lower process liner 162 and along wall surface 140 of chamber body 148. Slit valve liner 136 is positioned to protrude through upper process liner 132 and into the process region. Liners including funnel liner 122, retaining ring liner 128, upper process liner 132, lower process liner 162 and slit valve liner 136 are thermally insulating material, such as fused quartz, sapphire, PBN material, ceramic, silicon carbide, Aluminum 6061 T6, derivatives thereof or combinations thereof. In one embodiment, the liners may be stainless steel or aluminum or graphite and coated with a thermally insulating material as noted above. With a PBN coated liner, water vapor may not stick to the liner and hence, may not allow a precursor to react and deposit on the surface of the liner. Generally, the liners are stress relieved to prevent failure to thermal cycling during start-up and cool-down cycles of the deposition processes described herein. The liners are capable of withstanding temperatures of about 800 degrees Celsius or higher. In another embodiment, the liners may be capable of withstanding temperatures of about 1,000 degrees Celsius or higher. In yet another embodiment, the liners may be capable of withstanding temperatures of about 1,200 degrees Celsius or higher. Additionally, the liners may be flame polished to achieve a surface finish of about 2 microinches (about 0.051 μm) or less. The polished finish provides a smooth surface so that process reactants are delivered with little or no turbulence, as well as minimizes nucleation sites on the liners that may undesirably promote film growth thereon. Also, flame polishing removes surface flaws (e.g., pits and cracks) to minimize the nucleation of thermal stress-induced cracks.

Purge line 130 is a chamber back side purge line disposed from the bottom of chamber body 148 to chamber lid 120 and funnel liner 122. Purge line 130 is situated to allow a flow of purge gas between wall surface 140 and upper/lower process liners 132 and 162 and into the process region. A source of purge gas may be connected to purge line 130 through inlets 146. Purge gas flowing through purge line 136 buffers wall surface 140 from contaminants and excessive heat that may escape the process region. Contaminants include precursors or reaction products that may by-pass upper/lower process liners 132 and 162 to deposit on wall surface 140. Also, heat originating from the process region may evade upper/lower process liners 132 and 162 and absorb into process body 148. However, a stream of purge gas flowing through purge line 130 transports contaminants and heat back into the process region. Thermal choke plate 142 is disposed on the outside of chamber body 148 to prevent heat loss from the process region.

Upper process liner 132 and lower process liner 162 may contain lift pin holes to accept substrate lift pins (not shown) during movement of substrate 166. Upper process liner 132 and lower process liner 162 may be positioned within the process chamber to align lift pin holes. Upper process liner 132 further contains vacuum port 160, exhaust adaptor 154 and slit valve port 134 to accept slit valve liner 136. Exhaust adaptor 154 is positioned through chamber body 148 and vacuum port 160 so that the process region is in fluid communication with vacuum system 150. Substrates 166 pass through slit valve liner 136 to enter and exit process chamber 100. Slit valve liner 136 may also protrude through thermal choke plate 142.

Pumping efficiency may be controlled by using choke gap 156. Choke gap 156 is a space formed between the bottom edge of funnel liner 122 and the top of substrate support pedestal 164. Choke gap 156 is a circumferential gap that may be varied depending on the process conditions and the required pumping efficiency. Choke gap 156 is increased by lowering substrate support pedestal 164 or decreased by raising substrate support pedestal 164. The pumping conductance from the pumping port (not shown) in the lower portion of process chamber 100 to the center of expanding channel 116 is modified by changing the distance of choke gap 156 to control the thickness and the uniformity of a film during deposition processes described herein.

To increase the efficiency of exhausting gases from the chamber 100, a turbo molecular pump 152 may be added as a bypass or in-line with the vacuum pump 150. The turbo molecular pump 152 may be turned on as required or run continuously to aid in the removal of oxidizers from the chamber 100 and prevent them from mixing with the precursors. If the oxidizers mix with the precursors, reactions may occur and particulates may be generated.

The chamber lid 120 may be maintained at a constant temperature by heater rods 174 that may be coupled with the lid. The chamber body 148 may also be heated by heater rods 176. The heater rods 174, 176 may be electric or may have a heating fluid flowing therein. Alternatively, the heater rods 174, 176 may be replaced by a heat exchanger. The heat exchanger may cool the lid 120 and chamber body 148. By maintaining a constant temperature of the lid 120 and chamber body 148, precursor condensation may be reduced.

The substrate pedestal 164 may be heated or cooled. The substrate pedestal 164 may be cooled by a fluid flowing through a heat exchanger. Alternatively, the substrate pedestal 164 may be heated. The substrate pedestal 164 may have a dual zone heater so that the substrate 166 temperature may be controlled to be between about 150 degrees Celsius and about 800 degrees Celsius. In one embodiment, the temperature may be controlled to be between about 200 degrees Celsius and about 800 degrees Celsius. The dual zone heater permits control over various regions of the substrate 166 in order to enhance temperature uniformity from center to the edge of the substrate 166.

The ALD process may be conducted in a process chamber at a pressure in the range from about 1 Torr to about 100 Torr. In one embodiment, the pressure may be about 1 Torr to about 20 Torr. In yet another embodiment, the pressure may be from about 1 Torr to about 10 Torr. The pressure within the process chamber is less than the pressure in the reservoir that provides the precursor. The temperature of the substrate may be maintained in the range from about 70 degrees Celsius to about 1,000 degrees Celsius. In one embodiment, the range may be from about 100 degrees Celsius to about 650 degrees Celsius. In yet another embodiment, the range may be from about 250 degrees Celsius to about 500 degrees Celsius.

When forming a metal gate material, pulses of a tantalum containing compound, such as pentadimethylamino-tantalum (PDMAT; Ta(NMe₂)₅), may be introduced. The tantalum containing compound may be provided with the aid of a carrier gas, which includes, but is not limited to, helium (He), argon (Ar), nitrogen (N₂), hydrogen (H₂), and combinations thereof. Pulses of a nitrogen containing compound, such as ammonia, may be introduced. A carrier gas may also be used to help deliver the nitrogen containing compound. A purge gas, such as argon, may be introduced. In one aspect, the flow of purge gas may be continuously provided to act as a purge gas between the pulses of the tantalum containing compound and the nitrogen containing compound and to act as a carrier gas during the pulses of the tantalum containing compound and the nitrogen containing compound. In one aspect, delivering a purge gas through two gas conduits rather than a purge gas provided through one gas conduit. In one aspect, a reactant gas may be delivered through one gas conduit since uniformity of flow of a reactant gas, such as a tantalum containing compound or a nitrogen containing compound, is not as critical as uniformity of the purge gas due to the self-limiting absorption process of the reactants on the surface of substrate structures. In other embodiments, a purge gas may be provided in pulses. In other embodiments, a purge gas may be provided in more or less than two gas flows. In other embodiments, a tantalum containing gas may be provided in more than a single gas flow (i.e., two or more gas flows). In other embodiments, a nitrogen containing may be provided in more than a single gas flow (i.e., two or more gas flows).

Other examples of tantalum containing compounds, include, but are not limited to, other organo-metallic precursors or derivatives thereof, such as pentaethylmethylamino-tantalum (PEMAT; Ta[N(C₂H₅CH₃)₂]₅), pentadiethylamino-tantalum (PDEAT; Ta(NEt₂)₅,), and any and all derivatives of PEMAT, PDEAT, or PDMAT. Other tantalum containing compounds include without limitation TBTDET (Ta(NEt₂)₃NC₄H₉ or C₁₆H₃₉N₄Ta) and tantalum halides, for example TaX₅ where X is fluorine (F), bromine (Br) or chlorine (Cl), and/or derivatives thereof.

When forming a high k dielectric layer, a hafnium precursor may be introduced into the process chamber at a rate in the range from about 5 standard cubic centimeters per minute (sccm) to about 200 sccm. The hafnium precursor may be introduced with a carrier gas, such as nitrogen, with a total flow rate in the range from about 50 sccm to about 1,000 sccm. The hafnium precursor may be pulsed into the process chamber at a rate in a range from about 0.1 seconds to about 10 seconds, depending on the particular process conditions, hafnium precursor or desired composition of the deposited hafnium-containing material. In one embodiment, the hafnium precursor is pulsed into the process chamber at a rate in a range from about 1 second to about 5 seconds, for example, about 3 seconds. In another embodiment, the hafnium precursor is pulsed into the process chamber at a rate in a range from about 0.1 seconds to about 1 second, for example, about 0.5 seconds. In one example, the hafnium precursor is hafnium tetrachloride (HfCl₄). In another example, the hafnium precursor is a tetrakis(dialkylamino)hafnium compound, such as tetrakis(diethylamino)hafnium ((Et₂N)₄Hf or TDEAH).

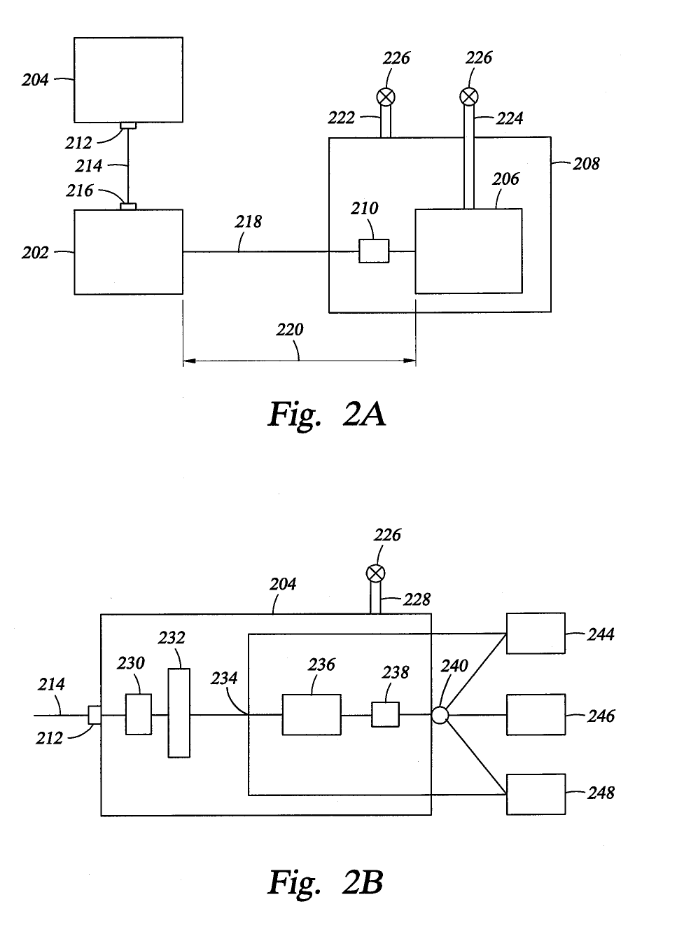

The hafnium or tantalum precursor may be dispensed into process chamber 202 by introducing a carrier gas through ampoule 206 containing the hafnium or tantalum precursor, as depicted in FIG. 2A. Ampoule 206 may include an ampoule, a bubbler, a cartridge or other container used for containing or dispersing chemical precursors. A suitable ampoule, such as the PROE-VAP™, is available from Advanced Technology Materials, Inc., located in Danbury, Conn. Ampoule 206 is in fluid communication with process chamber 202 by conduit 218. Conduit 218 may be a tube, a pipe, a line, a hose or other conduits known in the art. Also, ampoule 206 is at distance 220 from process chamber 202. Distance 220 is usually less than about 2 meters. In one embodiment, the distance 220 may be less than about 1.25 meters. In yet another embodiment, the distance 220 may be about 0.7 meters or less. Distance 220 may be minimized in order to maintain consistent hafnium or tantalum precursor flow. Also, while conduit 218 may be straight or have bends, conduit 218 is preferably straight or has as few bends as possible. Conduit 218 may be wrapped with a heating tape to maintain a predetermined temperature. The temperature of ampoule 206 is maintained at a temperature depending on the hafnium or tantalum precursor within, such as in a range from about 20 degrees Celsius to about 300 degrees Celsius. In one example, ampoule 206 contains HfCl₄ at a temperature in a range from about 150 degrees Celsius to about 200 degrees Celsius. It is to be understood that while hafnium has been exemplified as the high k dielectric material, zirconium may also be used.

In one embodiment, ampoule 206 may be part of a liquid delivery system containing injector valve system 210. The liquid delivery system is contained within a gas panel 208. Injector valve system 210 is connected to ampoule 206 and process chamber 202 by conduit 218. A source of carrier gas may be connected to injected valve system 210 (not shown). Ampoule 206 containing a liquid precursor (e.g., TDEAH, TDMAH, TDMAS or Tris-DMAS) may be pressurized to transfer the liquid precursor to injector valve system 210. Ampoule 206 containing a liquid precursor may be pressurized at a pressure in a range from about 138 kPa (about 20 psi) to about 414 kPa (about 60 psi) and may be heated to a temperature of about 100 degrees Celsius or less. In one embodiment, the temperature is in a range from about 20 degrees Celsius to about 60 degrees Celsius. Injector valve system 210 combines the liquid precursor with a carrier gas to form a precursor vapor that is injected into process chamber 202. A carrier gas may include nitrogen, argon, helium, hydrogen or combinations thereof and the carrier may be pre-heated to a temperature in a range from about 85 degrees Celsius to about 150 degrees Celsius. A suitable injector valve is available from Horiba-Stec, located in Kyoto, Japan.

The oxidizing gas may introduced to process chamber 202 with a flow a rate in the range from about 0.05 sccm to about 1,000 sccm. In one embodiment, the flow rate is in the range from about 0.5 sccm to about 100 sccm. The oxidizing gas may be pulsed into process chamber 202 at a rate in a range from about 0.05 seconds to about 10 seconds. In one embodiment, the range may be from about 0.08 seconds to about 3 seconds. In yet another embodiment, the range may be from about 0.1 seconds to about 2 seconds. In one embodiment, the oxidizing gas is pulsed at a rate in a range from about 1 second to about 5 seconds, for example, about 1.7 seconds. In another embodiment, the oxidizing gas is pulsed at a rate in a range from about 0.1 seconds to about 3 seconds, for example, about 0.5 seconds.

The oxidizing gas may be produced from a WVG system 204 in fluid communication with process chamber 202 by conduit 214. Fittings 212 and 216 may be used to link conduit 214 to WVG system 204 or to process chamber 202. Suitable fittings include UPG fittings available from Fujikin of America, Inc. Conduit 214 may be in fluid communication with process chamber 202 through an ALD valve assembly. Conduit 214 may be a tube, a pipe, a line or a hose composed of a metal (e.g., stainless steel or aluminum), rubber or plastic (e.g., PTFE). In one example, a pipe formed from stainless steel 316L is used as conduit 214. The WVG system 204 generates ultra-high purity water vapor by means of a catalytic reaction of an oxygen source gas (e.g., O₂) and a hydrogen source gas (e.g., H₂) at a low temperature (e.g., <500 degrees Celsius). The hydrogen and oxygen source gases each flow into WVG system 204 at a flow rate in the range from about 5 sccm to about 200 sccm. In one embodiment, the flow rate may be from about 10 sccm to about 100 sccm. The flow rates of the oxygen and hydrogen source gases may be independently adjusted to have a presence of oxygen or an oxygen source gas and an absence of the hydrogen or hydrogen source gas within the outflow of the oxidizing gas.

An oxygen source gas useful to generate an oxidizing gas containing water vapor may include oxygen (O₂), atomic oxygen (O), ozone (O₃), nitrous oxide (N₂O), nitric oxide (NO), nitrogen dioxide (NO₂), dinitrogen pentoxide (N₂O₅), hydrogen peroxide (H₂O₂), derivatives thereof or combinations thereof. A hydrogen source gas useful to generate an oxidizing gas containing water vapor may include hydrogen (H₂), atomic hydrogen (H), forming gas (N₂/H₂), ammonia (NH₃), hydrocarbons (e.g., CH₄), alcohols (e.g., CH₃OH), derivatives thereof or combinations thereof. A carrier gas may be co-flowed with either the oxygen source gas or the hydrogen source gas and may include N₂, He, Ar or combinations thereof. The oxygen source gas is oxygen or nitrous oxide and the hydrogen source gas is hydrogen or a forming gas, such as 5 volume percent of hydrogen in nitrogen.

A hydrogen source gas and an oxygen source gas may be diluted with a carrier gas to provide sensitive control of the water vapor within the oxidizing gas during deposition processes. In one embodiment, a slower water vapor flow rate (about <10 sccm water vapor) may be desirable to complete the chemical reaction during an ALD process to form a hafnium-containing material or other dielectric materials. A slower water vapor flow rate dilutes the water vapor concentration within the oxidizing gas. The diluted water vapor is at a concentration to oxidize adsorbed precursors on the substrate surface. Therefore, a slower water vapor flow rate minimizes the purge time after the water vapor exposure to increase the fabrication throughput. Also, the slower water vapor flow rate reduces formation of particulate contaminants by avoiding undesired co-reactions. A mass flow controller (MFC) may be used to control a hydrogen source gas with a flow rate of about 0.5 sccm while producing a stream of water vapor with a flow rate of about 0.5 sccm. However, most MFC systems are unable to provide a consistent flow rate at such a slow rate. Therefore, a diluted hydrogen source gas (e.g., forming gas) may be used in a WVG system to achieve a slower water vapor flow rate. In one example, a hydrogen source gas with a flow rate of about 10 sccm and containing 5 percent hydrogen forming gas delivers water vapor from a WVG system with a flow rate of about 0.5 sccm. In an alternative embodiment, a faster water vapor flow rate (about >10 sccm water vapor) may be desirable to complete the chemical reaction during an ALD process while forming a hafnium-containing material or other dielectric materials. For example, about 100 sccm of hydrogen gas delivers about 100 sccm of water vapor.

The forming gas may be selected with a hydrogen concentration in a range from about 1 percent to about 95 percent by volume in a carrier gas, such as argon or nitrogen. In one aspect, a hydrogen concentration of a forming gas is in a range from about 1 percent to about 30 percent by volume in a carrier gas. In one embodiment, the forming gas may be in a range from about 2 percent to about 20 percent. In yet another embodiment, the forming gas may be in a range from about 3 percent to about 10 percent. For example, a forming gas may contain about 5 percent hydrogen and about 95 percent nitrogen. In another aspect, a hydrogen concentration of a forming gas is in a range from about 30 percent to about 95 percent by volume in a carrier gas. In another embodiment, the hydrogen concentration may be from about 40 percent to about 90 percent. In yet another embodiment, the hydrogen concentration may be from about 50 percent to about 85 percent. For example, a forming gas may contain about 80 percent hydrogen and about 20 percent nitrogen.

In one example, a WVG system receives a hydrogen source gas containing 5 percent hydrogen (95 percent nitrogen) with a flow rate of about 10 sccm and an oxygen source gas (e.g., O₂) with a flow rate of about 10 sccm to form an oxidizing gas containing water vapor with a flow rate of about 0.5 sccm and oxygen with a flow rate of about 9.8 sccm. In another example, a WVG system receives a hydrogen source gas containing 5 percent hydrogen forming gas with a flow rate of about 20 sccm and an oxygen source gas with a flow rate of about 10 sccm to form an oxidizing gas containing water vapor with a flow rate of about 1 sccm and oxygen with a flow rate of about 9 sccm. In another example, a WVG system receives a hydrogen source gas containing hydrogen gas with a flow rate of about 20 sccm and an oxygen source gas with a flow rate of about 10 sccm to form an oxidizing gas containing water vapor at a rate of about 10 sccm and oxygen at a rate of about 9.8 sccm. In other examples, nitrous oxide, as an oxygen source gas, may be used with a hydrogen source gas to form a water vapor during ALD processes. Generally, 2 molar equivalents of nitrous oxide are substituted for each molar equivalent of oxygen gas.

A WVG system contains a catalyst, such as catalyst-lined reactor or a catalyst cartridge, in which the oxidizing gas containing water vapor is generated by a catalytic chemical reaction between a source of hydrogen and a source of oxygen. A WVG system is unlike pyrogenic generators that produce water vapor as a result of an ignition reaction, usually at temperatures over 1,000 degrees Celsius. A WVG system containing a catalyst usually produces water vapor at a low temperature in the range from about 100 degrees Celsius to about 500 degrees Celsius. In one embodiment, the temperature may be about 350 degrees Celsius or less. The catalyst contained within a catalyst reactor may include a metal or alloy, such as palladium, platinum, nickel, iron, chromium, ruthenium, rhodium, alloys thereof or combinations thereof. The ultra-high purity water is ideal for the ALD processes in the present invention. In one embodiment, to prevent unreacted hydrogen from flowing downstream, an oxygen source gas is allowed to flow through the WVG system for about 5 seconds. Next, the hydrogen source gas is allowed to enter the reactor for about 5 seconds. The catalytic reaction between the oxygen and hydrogen source gases (e.g., H₂ and O₂) generates a water vapor. Regulating the flow of the oxygen and hydrogen source gases allows precise control of oxygen and hydrogen concentrations within the formed oxidizing gas containing water vapor. The water vapor may contain remnants of the hydrogen source gas, the oxygen source gas or combinations thereof. Suitable WVG systems are commercially available, such as the WVG system by Fujikin of America, Inc., located in Santa Clara, Calif. and or the Catalyst Steam Generator System (CSGS) by Ultra Clean Technology, located in Menlo Park, Calif.

FIG. 2B illustrates one configuration of WVG system 204. Hydrogen source 244, oxygen source 248 and carrier gas source 246 may be coupled with WVG system 204 by conduit system 242. Conduit system 242 contains conduits and valves that allow gases from hydrogen source 244, oxygen source 248 and/or carrier gas source 246 to be independently in fluid communication with catalyst reactor 236 through gas inputs 240 and gas filter 238. Water vapor is formed within and emitted from catalyst reactor 236. Also, conduit system 242 contains conduits and valves that allow gases from hydrogen source 244 and oxygen source 248 to independently bypass catalyst reactor 236 at junction 234. Therefore, additional hydrogen source gas and/or oxygen source gas may bypass catalyst reactor 236 and combine with water vapor to form an oxidizing gas enriched with oxygen or hydrogen. Gas sensor 232 and gas filter 230 may be coupled with conduit system 242 downstream from catalyst reactor 236. Gas sensor 230 may be used to determine the composition of the oxidizing gas including oxygen, hydrogen and water concentrations. The oxidizing gas may pass through gas filter 230 prior to exiting WVG system 204.

The pulses of a purge gas may be introduced at a flow rate in a range from about 2 standard liters per minute (slm) to about 22 slm. In one embodiment, the purge gas may be argon or nitrogen. In another embodiment, the flow rate may be about 10 slm. Each processing cycle occurs for a time period in a range from about 0.01 seconds to about 20 seconds. In one example, the process cycle lasts about 10 seconds. In another example, the process cycle lasts about 2 seconds. Longer processing steps lasting about 10 seconds deposit excellent hafnium-containing films, but reduce the throughput. The specific purge gas flow rates and duration of process cycles are obtained through experimentation. In one example, a 300 mm diameter wafer requires about twice the flow rate for the same duration as a 200 mm diameter wafer in order to maintain similar throughput.

In one embodiment, hydrogen gas may be used as a carrier gas, purge gas and/or a reactant gas to reduce halogen contamination from the deposited materials. Precursors that contain halogen atoms (e.g., HfCl₄, SiCl₄ and Si₂Cl₆) readily contaminate the deposited dielectric materials. Hydrogen is a reductant and will produce hydrogen halides (e.g., HCl) as a volatile and removable by-product. Therefore, hydrogen may be used as a carrier gas or reactant gas when combined with a precursor compound (e.g., hafnium, silicon, oxygen precursors) and may include another carrier gas (e.g., Ar or N₂). In one example, a water/hydrogen mixture, at a temperature in the range from about 100 degrees Celsius to about 500 degrees Celsius, may be used to reduce the halogen concentration and increase the oxygen concentration of the deposited material. In one example, a water/hydrogen mixture may be derived by feeding an excess of hydrogen source gas into a WVG system to form a hydrogen enriched water vapor.

In one embodiment, the hafnium precursor may be dispensed into process chamber 202 by introducing a carrier gas through ampoule 206 containing the hafnium precursor, as depicted in FIG. 2A. The temperature of ampoule 206 may be maintained at a temperature depending on the hafnium precursor within, such as in a range from about 20 degrees Celsius to about 300 degrees Celsius. In one example, ampoule 206 contains HfCl₄ at a temperature in a range from about 150 degrees Celsius to about 200 degrees Celsius. In another example, ampoule 206 containing a liquid precursor (e.g., TDEAH, TDMAH, TDMAS or Tris-DMAS) may be pressurized to transfer the liquid precursor to injector valve system 210. Generally, ampoule 206 containing a liquid precursor may be pressurized at a pressure in a range from about 138 kPa (about 20 psi) to about 414 kPa (about 60 psi) and may be heated to a temperature of about 100 degrees Celsius or less. In one embodiment, the temperature may be from about 20 degrees Celsius to about 60 degrees Celsius. Injector valve system 210 combines the liquid precursor with a carrier gas to form a precursor vapor that is injected into process chamber 202. A carrier gas may include nitrogen, argon, helium, hydrogen or combinations thereof and the carrier may be pre-heated to a temperature in a range from about 85 degrees Celsius to about 150 degrees Celsius.

Oxidizing gas containing water vapor is introduced into process chamber 202 at a rate in the range from about 20 sccm to about 1,000 sccm. In one embodiment, the rate may be from about 50 sccm to about 200 sccm. The oxidizing gas is pulsed into process chamber 202 a rate in a range from about 0.1 seconds to about 10 seconds, depending on the particular process conditions and desired composition of the deposited hafnium-containing material. In one embodiment, the oxidizing gas is pulsed at a rate from about 1 second to about 3 seconds, for example, about 1.7 seconds. In another embodiment, the oxidizing gas is pulsed at a rate from about 0.1 seconds to about 1 second, for example, about 0.5 seconds.

The oxidizing gas may be produced from WVG system 204 that is in fluid communication with process chamber 202 by conduits 214, 216. A hydrogen source gas (H₂) and an oxygen source gas (O₂) each flow independently into WVG system 204 with a flow rate in a range from about 20 sccm to about 300 sccm. The oxygen source gas may be provided at a higher flow rate than the hydrogen source gas. In one example, the hydrogen source gas may have a flow rate of about 100 sccm and oxygen source gas may have a flow rate of about 120 sccm to enrich the water vapor with oxygen.

In some of the embodiments, an alternative oxidizing gas, such as a traditional oxidant, may be used instead of the oxidizing gas containing water vapor formed from a WVG system. The alternative oxidizing gas may be introduced into the process chamber from an oxygen source containing water not derived from a WVG system includes oxygen (O₂), ozone (O₃), atomic-oxygen (O), hydrogen peroxide (H₂O₂), nitrous oxide (N₂O), nitric oxide (NO), dinitrogen pentoxide (N₂O₅), nitrogen dioxide (NO₂), derivatives thereof or combinations thereof. While embodiments of the invention provide processes that benefit from oxidizing gas containing water vapor formed from a WVG system, other embodiments provide processes that utilize the alternative oxidizing gas or traditional oxidants while forming hafnium-containing materials and other dielectric materials during deposition processes described herein.

Exemplary hafnium precursors include hafnium compounds containing ligands such as halides, alkylaminos, cyclopentadienyls, alkyls, alkoxides, derivatives thereof or combinations thereof. Hafnium halide compounds useful as hafnium precursors may include HfCl₄, Hfl₄, and HfBr₄. Hafnium alkylamino compounds useful as hafnium precursors include (RR′N)₄Hf, where R or R′ are independently hydrogen, methyl, ethyl, propyl or butyl. Hafnium precursors useful for depositing hafnium-containing materials include (Et₂N)₄Hf, (Me₂N)₄Hf, (MeEtN)₄Hf, (^{t}BuC₅H₄)₂HfCl₂, (C₅H₅)₂HfCl₂, (EtC₅H₄)₂HfCl₂, (Me₅C₅)₂HfCl₂, (Me₅C₅)HfCl₃, (ⁱPrC₅H₄)₂HfCl₂, (ⁱPrC₅H₄)HfCl₃, (^{t}BuC₅H₄)₂HfMe₂, (acac)₄Hf, (hfac)₄Hf, (tfac)₄Hf, (thd)₄Hf, (NO₃)₄Hf, (^{t}BuO)₄Hf, (ⁱPrO)₄Hf, (EtO)₄Hf, (MeO)₄Hf or derivatives thereof. In one embodiment, the hafnium precursors used during the deposition process herein include HfCl₄, (Et₂N)₄Hf or (Me₂N)₄Hf.

Exemplary silicon precursors useful for depositing silicon-containing materials include silanes, alkylaminosilanes, silanols or alkoxy silanes, for example, silicon precursors may include (Me₂N)₄Si, (Me₂N)₃SiH, (Me₂N)₂SiH₂, (Me₂N)SiH₃, (Et₂N)₄Si, (Et₂N)₃SiH, (MeEtN)₄Si, (MeEtN)₃SiH, Si(NCO)₄, MeSi(NCO)₃, SiH₄, Si₂H₆, SiCl₄, Si₂Cl₆, MeSiCl₃, HSiCl₃, Me₂SiCl₂, H₂SiCl₂, MeSi(OH)₃, Me₂Si(OH)₂, (MeO)₄Si, (EtO)₄Si or derivatives thereof. Other alkylaminosilane compounds useful as silicon precursors include (RR′N)₄₋ₙSiHₙ, where R or R′ are independently hydrogen, methyl, ethyl, propyl or butyl and n=0-3. Other alkoxy silanes may be described by the generic chemical formula (RO)₄₋ₙSiLₙ, where R=methyl, ethyl, propyl or butyl and L=H, OH, F, Cl, Br or I and mixtures thereof. Also, higher silanes are used as silicon precursors within some embodiments of the invention. Higher silanes are disclosed in commonly assigned United States Patent Publication No. 2004/0224089, which is incorporated herein by reference in entirety. In one embodiment, the silicon precursors used during the deposition process herein include (Me₂N)₃SiH, (Et₂N)₃SiH, (Me₂N)₄Si, (Et₂N)₄Si or SiH₄.

Exemplary nitrogen precursors may include: NH₃, N₂, hydrazines (e.g., N₂H₄ or MeN₂H₃), amines (e.g., Me₃N, Me₂NH or MeNH₂), anilines (e.g., C₆H₅NH₂), organic azides (e.g., MeN₃ or Me₃SiN₃), inorganic azides (e.g., NaN₃ or CP₂CoN₃), radical nitrogen compounds (e.g., N₃, N₂, N, NH or NH₂), derivatives thereof or combinations thereof. Radical nitrogen compounds may be produced by heat, hot-wires or plasma.

In one embodiment, the precursor is a liquid. Liquid precursors may be delivered to the chamber 100 by a direct injection method. Some useful precursors include flammable precursors, pyrophoric precursors, and toxic precursors. Suitable flammable precursors include HfCl₄, La(THD)₂, Pr(THD)₃, Pr(N(SiMe₃)₂)₃, La(N(SiMe₃)₂)₃), La(i-Pr-AMD)₃, TAETO, TDMAH, DMAH, and TMAI as solid flammable precursors. Flammable liquid precursors include TDEAHf, TDEAZr, TEMAHf, TEMAZr, 4-DMAS, 3-DMAS, TBTDET, TBTEMT, IPTDET, IPTEMT, DMEEDMAA, EBDA, TDEAS, TEMAS, and BTBAS. Suitable viscous and pyrophoric precursors include Me₃Al, Me₂AlH, and other organo-aluminum compounds. Suitable toxic or pyrophoric or reactive gas precursors include AsH₃, GeH₄, SiH₄, NH₃, PH₃, Si₂H₆, B₂H₆, NO, dichlorosilane, hexachlorosilane, and N₂O. The precursors may be delivered by bubbling or through the liquid delivery system in a range of about room temperature to about 300 degrees Celsius. Solid precursors may be heated to ensure that the precursors remain in liquid form by covering the precursor source with heater tape or a heater jacket. A heater jacket or tape may be installed on top of a solid precursor source to prevent the precursor from leaking and coming into contact with the heater jacket.

When using precursors that may be toxic, flammable, or pyrophoric, it may be beneficial to have an exhaust system to ensure that harmful gases do not build-up within the chamber components. For example, when a technician needs to service the gas panel 208, precursor gases may have leaked into the panel. Due to the high heat of the chamber 100, it is possible for the precursors to ignite and hence, injure the technician or others. Thus, an exhaust conduit 222 may be coupled with the gas panel 208. The exhaust conduit 222 may have a valve 226 that when open, allows the gas panel 208 to vent. The vent may be coupled to an exhaust fan.

Similarly, when the ampoule 206 needs servicing, it would be beneficial to remove any harmful gases that have built up. An exhaust conduit 224 may be coupled with the ampoule 206 to vent harmful gases out of the ampoule 206. The exhaust conduit may have a valve 226 coupled therewith that when open, allows the harmful gases to vent.

In another embodiment, the water vapor generator system 204 may have an exhaust conduit 228 that vents through an open valve 226. The exhaust conduit 228 coupled with the water vapor generator system 204 allows evacuation of gases that have leaked.

By providing exhaust conduits 224, 226, 228, the chamber 100 may handle flammable, toxic, and pyrophoric precursors in a safe and efficient manner.

While the foregoing is directed to embodiments of the present invention, other and further embodiments of the invention may be devised without departing from the basic scope thereof, and the scope thereof is determined by the claims that follow.

1. A vapor deposition apparatus, comprising:
a liquid precursor or solid precursor delivery cabinet having an exhaust line coupled therewith;
a gas panel having an exhaust line coupled therewith;
a water vapor generator system having an exhaust line coupled therewith; and
one or more toxic, flammable, or pyrophoric precursor sources.

2. The apparatus of claim 1, further comprising heater rods coupled with a lid of the apparatus.

3. The apparatus of claim 1, further comprising a turbo molecular pump coupled with the apparatus.

4. The apparatus of claim 1, further comprising a chamber, wherein the chamber has a liner coupled therewith.

5. The apparatus of claim 4, wherein the liner comprises stainless steel, quartz, aluminum, sapphire, graphite, or ceramic material.

6. The apparatus of claim 5, wherein the liner is coated with PBN, SiC, quartz, or aluminum.

7. The apparatus of claim 1, wherein the apparatus is an atomic layer deposition apparatus.

8. The apparatus of claim 1, wherein the apparatus is a chemical vapor deposition apparatus.

9. The apparatus of claim 1, further comprising a heat exchanger coupled with the apparatus.

10. The apparatus of claim 1, further comprising a dual zone heated pedestal coupled with the apparatus.

11. A vapor deposition method, comprising:
introducing at least one precursor to an apparatus, the apparatus having a liquid precursor or solid precursor delivery cabinet, a gas panel, and a water vapor generator system, the precursor selected from the group consisting of toxic precursors, flammable precursors, and pyrophoric precursors;
venting precursor gas from at least one of the liquid delivery cabinet, gas panel, or water vapor generator system; and
depositing a layer on a substrate.

12. The method of claim 11, wherein the toxic precursor is selected from the group consisting of AsH₃, GeH₄, SiH₄, NH₃, PH₃, Si₂H₆, B₂H₆, NO, dichlorosilane, hexachlorosilane, and N₂O.

13. The method of claim 11, wherein the flammable precursor is selected from the group consisting of HfCl₄, La(THD)₂, Pr(THD)₃, Pr(N(SiMe₃)₂)₃, La(N(SiMe₃)₂)₃), La(i-Pr-AMD)₃, TAETO, TDMAH, DMAH, and TMAI.

14. The method of claim 11, wherein the flammable precursor is selected from the group consisting of TDEAHf, TDEAZr, TEMAHf, TEMAZr, 4-DMAS, 3-DMAS, TBTDET, TBTEMT, IPTDET, IPTEMT, DMEEDMAA, EBDA, TDEAS, TEMAS, and BTBAS.

15. The method of claim 11, wherein the pyrophoric precursor is selected from the group consisting of Me₃Al, Me₂AlH, and organo-aluminum compounds.

16. The method of claim 11, wherein the precursor is a liquid precursor and further comprising directly injecting the liquid precursor.

17. The method of claim 11, wherein the layer is deposited by atomic layer deposition.

18. The method of claim 11, wherein the layer is deposited by chemical vapor deposition.

19. The method of claim 11, wherein the layer deposited is a high k dielectric layer or a metal gate layer.

20. The method of claim 11, wherein the layer deposited comprises hafnium.
